(19) United States
(12) Patent Application Publication
(10) Pub. No.: US 2008/0247439 A1
(43) Pub. Date: Oct. 9, 2008

(54) Semiconductor Laser Device and Method for Fabrication Thereof

(76) Inventors: Yozo Uchida, Aichi (JP); Kenji Nakashima, Tottori (JP); Seiji Kawamoto, Tottori (JP)

Correspondence Address: MCDERMOTT WILL & EMERY LLP, 600 13TH STREET, N.W., WASHINGTON, DC, 20005-3096, US

(21) Appl. No.: 10/593,102

(22) PCT Filed: Mar. 2, 2005
(86) PCT No.: PCT/JP2005/003511

§ 371 Date: Sep. 15, 2006

(30) Foreign Application Priority Data
Mar. 15, 2004 (JP) 2004-071971
Mar. 18, 2004 (JP) 2004-077691

(51) Int. Cl. H01S 3/097; H01L 21/02

(52) U.S. Cl. 372/87; 438/39

(57) ABSTRACT

In a semiconductor laser device (LD1), a semiconductor laser layer is formed on one face of a semiconductor substrate (1), and a p-type electrode (8) and an n-type electrode (11) are provided on the semiconductor laser layer side and the semiconductor substrate (1) side, respectively, so as to sandwich the semiconductor laser layer and the semiconductor substrate (1) therebetween. The p-type electrode (8) includes a first electrode (9) and a second electrode (10) that covers the first electrode (9).

### TECHNICAL FIELD

The present invention relates to, for example, a ridge stripe semiconductor laser device and a method for fabrication thereof.

### BACKGROUND ART

Conventionally, there have been fabricated semiconductor laser devices described under (1) and (2) below.

(1) For example, a conventional ridge stripe semiconductor laser device disclosed in Patent Publication 1 has a structure shown in FIG. 8.

Specifically, on an n-type semiconductor substrate 100, an n-type clad layer 101, an active layer 102, a p-type clad layer 103, and a p-type contact layer 104 are first sequentially laid on top of another in this order in the first crystal growth.

Subsequently, a stripe-shaped ridge 105 is formed in the p-type clad layer 103 and the p-type contact layer 104. Then, a current block layer 106 is formed, except the tip portion of the ridge 105, in the second crystal growth.

Then, in the third crystal growth, a p-type buried layer 107 is formed in such a way that it covers the entire surfaces of the ridge 105 and the current block layer 106. Finally, an n-type electrode 108 is formed on the underside of the n-type semiconductor substrate 100, and a p-type electrode 109 is formed on top of the p-type buried layer 107.

(2) For example, a semiconductor laser device disclosed in Patent Publication 2 is a dual-wavelength semiconductor laser device in which two semiconductor laser portions having different wavelengths are arranged side by side on a single semiconductor substrate.

In this semiconductor laser device, a first multiple-layer member composing a first semiconductor laser portion (L11′; see FIG. 9, which will be described later) is crystal grown on a semiconductor substrate, and, in addition to the first multiple-layer member, a given region is allocated to form a second semiconductor laser portion (L12′; see FIG. 9, which will be described later).

Specifically, part of the first multiple-layer member is etched at a time (removed in a single session of etching) so as to expose the semiconductor substrate.

Then, on the substrate on which the first multiple-layer member composing the first semiconductor laser portion is left unetched, the second multiple-layer member composing the second semiconductor laser portion is crystal grown.

Then, the second multiple-layer member formed on the first multiple-layer member is removed by etching so as to form the second semiconductor laser portion, and then electrodes for the first and second semiconductor laser portions are formed.
Patent Publication 1: JP-B-3075728
Patent Publication 2: JP-A-2001-244569

### DISCLOSURE OF THE INVENTION

### Problems to be Solved by the Invention

The semiconductor laser devices described under (1) and (2) suffer from the following problems (problem 1 and problem 2). This makes it difficult to improve the characteristics of a semiconductor laser device (improve the device characteristic).

(Problem 1)

In the conventional semiconductor laser device described under (1), a p-type buried layer 107 is formed. This disadvantageously increases fabrication costs. In addition to this, it is necessary to perform a crystal growth step three times. This also disadvantageously increases the number of fabrication processes.

Furthermore, a junction-down mounting with the active layer down is adopted in this conventional semiconductor laser device. As a result, the p-type buried layer 107 is located on the path along which heat of the active layer is dissipated. This undesirably lengthens the heat dissipation path, resulting in unsatisfactory heat dissipation.

Thus, to solve the conventionally encountered problems discussed above, we have studied a new structure from which the p-type buried layer 107 is removed, only to find that, when the p-type buried layer 107 is removed and the p-type electrode 109 is formed directly on the ridge 105 and the current block layer 106, spreading of current becomes insufficient, and, in particular, both ends of the stripe-shaped ridge are not fed with sufficient current.

To solve such a shortage of current, we have studied a structure in which the p-type electrode 109 is extended to each end of the ridge. However, when cleavage is performed at both ends of the ridge so as to form resonator facets, the following problem (defect) arises. At the time of cleavage, part of the p-type electrode 109 comes off due to the thickness of the p-type electrode 109.

If such a defect (coming-off of the electrode) occurs, the semiconductor laser device cannot obtain desired device characteristics (resulting in a defective device).

(Problem 2)

In the conventional semiconductor laser device described under (2), when a region for a second semiconductor laser portion (L12′) is formed, the first multiple-layer member is etched at a time (removed in a single session of etching). In that case, due to the removal performed in a single session of etching, projections and depressions in the uppermost layer of the first multiple-layer member may affect the surface of the exposed semiconductor substrate.

Specifically, the projections and depressions in the uppermost layer of the first multiple-layer member lead to the formation of projections and depressions on the surface of the semiconductor substrate, and these projections and depressions on the surface of the semiconductor substrate eventually degrade the crystallinity of a second multiple-layer member that is crystal grown on this semiconductor substrate.

A detailed description will be given below. As shown in FIG. 9, after crystal growth (first crystal growth) is performed so as to form a first multiple-layer member composing a first semiconductor laser portion (L11′), crystal growth (second crystal growth) is performed so as to form a second multiple-layer member composing a second semiconductor laser portion (L12′).

In that case, the second crystal growth is performed at a lower temperature than the first crystal growth. If the second crystal growth is performed at such a low temperature, the crystallinity of the uppermost layer (see “a”) is affected by the low temperature growth and thus becomes lower than that of a layer formed below the uppermost layer (see “b”).

In particular, when the first crystal growth layer and the second crystal growth layer are etched at a time, the surface (that is, the semiconductor substrate) exposed after the removal tends to exhibit a poor crystallinity (see “c”) because it inherits the shape from the uppermost layer.

If crystal growth is performed on the surface of the semiconductor substrate with a poor crystallinity to form a second semiconductor laser portion (L12′), the crystallinity thereof tends to deteriorate. Such a poor crystallinity of the semiconductor laser portion undesirably leads to unsatisfactory device characteristics of the semiconductor laser device (resulting in a defective device).

An object of the present invention is to provide a semiconductor laser device that can not only reduce the number of parts and fabrication processes but also offer satisfactory heat dissipation by removing a p-type buried layer and the like.

Another object of the present invention is to provide a semiconductor laser device with a reduced incidence of defective devices resulting from coming off of an electrode or crystallinity deterioration, for example.

### Means for Solving the Problem

According to the present invention, a semiconductor laser device is provided with a semiconductor laser layer formed on one face of a semiconductor substrate, and a first type electrode and a second type electrode provided on the semiconductor laser layer side and the semiconductor substrate side, respectively, so as to sandwich the semiconductor laser layer and the semiconductor substrate therebetween. Here, the first type electrode includes a first electrode and a second electrode that covers the first electrode.

A method for fabricating such a semiconductor laser device, that is, a first type electrode forming step includes a first electrode forming step of forming a first electrode and a second electrode forming step of forming a second electrode.

As described above, the first type electrode is made to have a two-layer structure including a first electrode and a second electrode. This permits the first type electrode to have different shapes, for example, a shape that can suitably deal with cleavage (device separation) performed to form a semiconductor laser device.

For example, when the semiconductor laser layer has a stripe-shaped and raised ridge, it is preferable that the first electrode be so formed as to cover at least a top portion of the ridge, and the second electrode be so formed as to have an area smaller than an area occupied by the semiconductor laser layer.

That is, there is included a ridge forming step of forming a stripe-shaped and raised ridge in the semiconductor laser layer. After the ridge forming step is performed, the first electrode forming step is performed so that the first electrode is so formed as to cover at least a top portion of the ridge.

Then, the second electrode forming step is performed so that the second electrode is so formed as to have an area smaller than an area occupied by the semiconductor laser layer.

By doing this, the first electrode covers the entire area of the top face of the ridge. This makes it possible to feed sufficient current to both stripe-direction ends of the ridge. In addition to this, the second electrode is made to have an area smaller than an area occupied by the semiconductor laser layer.

For example, the second electrode is so formed as to be away from the edges of the semiconductor laser layer. That is, in the second electrode forming step, the second electrode is so formed as to be away from the edges of the semiconductor laser layer.

By doing this, cleaved facets (cleaved lines) formed at the time of device separation do not overlap the second electrode. This reduces the possibility of the second electrode coming off the first electrode due to cleavage.

Preferably, the film thickness of the first electrode is made thinner than that of the second electrode. Specifically, it is preferable that the film thickness of the first electrode be 10 nm or more but 30 nm or less.

This makes it possible to prevent the possibility that the first electrode becomes so thick that it comes off at the time of cleavage.

Furthermore, when device facets (cleaved facets) are formed by cleavage, device separation (cleavage) is performed on the first electrode that is resistant to coming off because it is sufficiently thinner than the second electrode. This makes it possible to reliably eliminate the possibility of the second electrode coming off at the time of device separation.

When a plurality of ridges are formed, for example, when a plurality of semiconductor laser portions, each emitting laser light, are formed on a monolithic semiconductor substrate (in the case of a monolithic semiconductor laser device), it is preferable that the second electrode be so formed as to have an area smaller than an area occupied by the semiconductor laser layer corresponding to each ridge.

That is, when a plurality of ridges are formed in the ridge forming step, the second electrode is so formed, in the second electrode forming step, as to have an area smaller than an area occupied by-the semiconductor laser layer corresponding to each ridge.

This makes it possible to obtain the aforementioned benefits.

Preferably, the semiconductor laser layer has a groove for separating the plurality of ridges from each other, and the first electrode is formed within an area occupied by each semiconductor laser layer separated by the groove.

That is, according to the present invention, a method for fabricating a semiconductor laser device includes a groove forming step of forming a groove for separating the plurality of ridges from each other, the plurality of ridges formed by the ridge forming step. Here, in the first electrode forming step, the first electrode is formed within an area occupied by each semiconductor laser layer separated by the groove formed by the groove forming step.

By doing this, the first electrode is prevented from being formed inside the groove (separation groove) thus formed. This makes the different semiconductor laser portions electrically disconnected from each other. This eliminates the possibility of deterioration of the device characteristics of the semiconductor laser device due to, for example, a short circuit resulting from the formation of the first electrode inside the separation groove.

Preferably, in the semiconductor laser device of the present invention, the film thickness of the first electrode is made thinner than that of the second electrode. Specifically, it is preferable that the film thickness of the first electrode be 10 nm or more but 30 nm or less.

This makes it possible to prevent the possibility that the first electrode becomes so thick that it comes off at the time of cleavage.

Preferably, at least one of the first electrode forming step and the second electrode forming step uses lift-off for electrode formation.

This is because the use of lift-off makes it easy to form electrodes having different film thicknesses such as thick film electrodes or thin film electrodes.

In the method for fabricating a semiconductor laser device according to the present invention, the semiconductor laser layer forming process for forming a semiconductor laser layer in which the plurality of ridges are formed includes a plurality of semiconductor laser portion forming steps of forming semiconductor laser layers corresponding to the different ridges.

The plurality of semiconductor laser portions forming steps each include a plurality of stages of semiconductor crystal growth steps, and a plurality of removing steps of removing semiconductor laser layers formed by the different stages of semiconductor crystal growth steps.

For example, it is preferable that the plurality of removing steps be performed in different stages, and each removing step removes a corresponding one of the semiconductor laser layers formed by the different stages of semiconductor crystal growth steps.

As described above, the semiconductor laser layer forming process includes a plurality of semiconductor laser portion forming steps corresponding to the different semiconductor laser layers (semiconductor laser portions), and a plurality of stages of semiconductor crystal growth steps are performed to form each of the different semiconductor laser portions.

That is, each semiconductor laser portion includes a plurality of semiconductor crystals (crystal growth layers). Furthermore, the method for fabricating a semiconductor laser device according to the present invention includes different removing steps corresponding to the plurality of crystal growth layers (that is, different removing steps each removing only corresponding one of the plurality of crystal growth layers).

For example, in a monolithic semiconductor laser device, a plurality of semiconductor laser portions are formed on a monolithic semiconductor substrate. It is for this reason that the semiconductor laser portions are located in different regions on the monolithic semiconductor substrate.

In that case, after one semiconductor laser portion (a semiconductor laser layer corresponding to one ridge) is formed on the semiconductor substrate through one semiconductor laser portion forming step, it is necessary to remove the semiconductor laser layer corresponding to a region (remaining region) other than the semiconductor laser portion thus formed, because the other semiconductor laser portion is formed in this remaining region.

Here, in the method for fabricating a semiconductor laser device according to the present invention, the semiconductor laser layer that has already been formed is removed in different stages. Specifically, the semiconductor laser layer including a plurality of semiconductor crystals (crystal growth layers) is removed in such a way that the different semiconductor crystals are removed one by one.

That is, the method for fabricating a semiconductor laser device according to the present invention includes a plurality of removing steps, one for each of the different crystal growth layers, for removing the crystal growth layers, whereby the semiconductor laser layer is removed in different stages.

Conventionally, since the semiconductor laser layer is removed (for example, etched) in one process, the poor flatness (for example, projections and depressions) of the uppermost layer of the semiconductor laser layer leads to degradation of the flatness of the exposed surface of the semiconductor substrate.

However, when removal is performed in different stages as in the method for fabricating a semiconductor laser device according to the present invention, the adverse influences of the poor flatness of the uppermost layer are cancelled out by an earlier removing step performed before a removing step by which the semiconductor substrate is exposed. That is, the semiconductor substrate is prevented from being directly affected by the projections and depressions, for example, formed in the uppermost layer.

As described above, through a plurality of removing steps, the exposed surface of the semiconductor substrate achieves a very high degree of flatness. This helps improve the crystallinity of the semiconductor laser layer of the other semiconductor laser portion, making it possible to form a semiconductor laser device having desired device characteristics.

Preferably, in the different stages of semiconductor crystal growth steps, a crystal growth temperature in a later semiconductor crystal growth step is made lower than a crystal growth temperature in an earlier semiconductor crystal growth step.

### ADVANTAGES OF THE INVENTION

According to the present invention, it is possible to fabricate a semiconductor laser device with reduced incidence of defective devices resulting from coming off of an electrode or crystallinity deterioration, for example.

### BRIEF DESCRIPTION OF DRAWINGS

FIG. 1A perspective view of the semiconductor laser device of a first embodiment of the present invention.

FIG. 2A perspective view of the semiconductor laser device of a second embodiment of the present invention.

FIG. 3A perspective view of the semiconductor laser device of a third embodiment of the present invention.

FIG. 4A perspective view of the semiconductor laser device of a fourth embodiment of the present invention.

FIG. 5A A first semiconductor crystal growth step in a process diagram showing a method for fabricating the semiconductor laser device of a fifth embodiment of the present invention.

FIG. 5B A first ridge forming step in the process diagram showing the method for fabricating the semiconductor laser device of the fifth embodiment of the present invention.

FIG. 5C A second semiconductor crystal growth step in the process diagram showing the method for fabricating the semiconductor laser device of the fifth embodiment of the present invention.

FIG. 5D A first removing step in the process diagram showing the method for fabricating the semiconductor laser device of the fifth embodiment of the present invention.

FIG. 5E A second removing step in the process diagram showing the method for fabricating the semiconductor laser device of the fifth embodiment of the present invention.

FIG. 5F A third semiconductor crystal growth step in the process diagram showing the method for fabricating the semiconductor laser device of the fifth embodiment of the present invention.

FIG. 6G A third removing step in the process diagram of the method for fabricating the semiconductor laser device of the fifth embodiment of the present invention.

FIG. 6H A second ridge forming step in the process diagram showing the method for fabricating the semiconductor laser device of the fifth embodiment of the present invention.

FIG. 6I A fourth semiconductor crystal growth step in the process diagram showing the method for fabricating the semiconductor laser device of the fifth embodiment of the present invention.

FIG. 6J An opening forming step in the process diagram showing the method for fabricating the semiconductor laser device of the fifth embodiment of the present invention.

FIG. 6K An electrode forming step in the process diagram showing the method for fabricating the semiconductor laser device of the fifth embodiment of the present invention.

FIG. 7 A perspective view showing the dual-wavelength monolithic semiconductor laser device.

FIG. 8 A perspective view of a conventional semiconductor laser device.

FIG. 9 A front view showing part of a method for fabricating a conventional semiconductor laser device.

### LIST OF REFERENCE SYMBOLS

1 semiconductor substrate

2 n-type clad layer (semiconductor laser layer)

3 active layer (semiconductor laser layer)

4 p-type clad layer (semiconductor laser layer)

5 p-type contact layer (semiconductor laser layer)

6 ridge

7 block layer

8 p-type electrode (first type electrode)

9 first electrode

10 second electrode

11 n-type electrode (second type electrode)

12 separation groove (groove)

21 semiconductor substrate

22 multiple-layer structure (first crystal growth layer)

23 n-type clad layer (semiconductor laser layer)

24 active layer (semiconductor laser layer)

25 p-type clad layer (semiconductor laser layer)

26 p-type GaAs layer (contact layer; semiconductor laser layer)

27 ridge

30 multiple-layer structure (second crystal growth layer; semiconductor laser layer)

31 multiple-layer structure (third crystal growth layer; semiconductor laser layer)

38 ridge

42 p-electrode (first type electrode)

43 p-electrode (first type electrode)

44 n-electrode (second type electrode)

LDs 1 to 5 semiconductor laser devices

L1 semiconductor laser portion

L2 semiconductor laser portion

L11 semiconductor laser portion

L12 semiconductor laser portion

### Best for Carrying Out the Invention

How the present invention is carried out will be described below with reference to the accompanying drawings.

### First Embodiment

[Semiconductor Laser Device LD1]

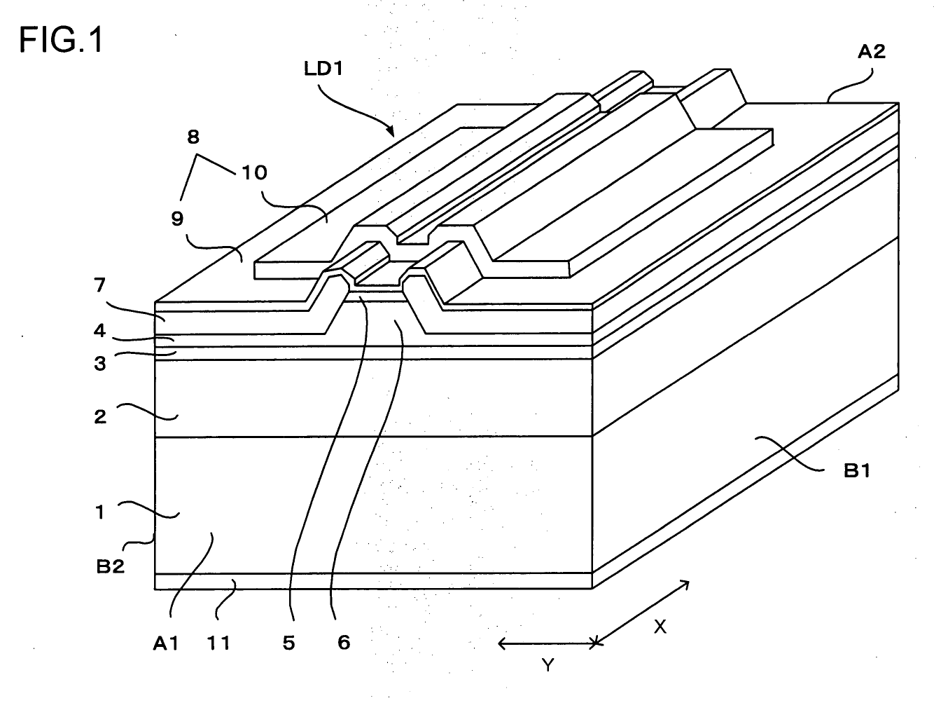

FIG. 1 is a perspective view of a single beam semiconductor laser device LD1.

<First Crystal Growth>

In this semiconductor laser device LD1, an n-type clad layer 2, an active layer 3, a p-type clad layer 4, and a p-type contact layer 5 are laid on top of another in this order on an n-type semiconductor substrate 1 having a given area (that is, from the semiconductor substrate 1 side).

In the first crystal growth (semiconductor crystal growth step), the n-type clad layer 2, the active layer 3, the p-type clad layer 4, and the p-type contact layer 5 are sequentially laid on top of another.

Furthermore, the n-type clad layer 2 and the p-type clad layer 4 form a double-hetero structure, in which the active layer 3 is sandwiched between them. That is, the n-type clad layer 2 and the p-type clad layer 4 support the active layer 3 by sandwiching it between them.

Such a double-hetero structure helps form a semiconductor having a greater bandgap energy than that of the active layer 3.

Incidentally, the light-emitting wavelength of the semiconductor laser device LD1 depends on a material of the active layer 3, in particular, the bandgap energy thereof. That is, by appropriately selecting the materials of the active layer 3, and the n-type clad layer 2 located above it and the p-type clad layer 4 located below it (clad layers 2 and 4), it is possible to select the light-emitting wavelength from infrared to ultraviolet.

If necessary, an n-type buffer layer may be located between the semiconductor substrate 1 and the n-type clad layer 2. Also, if necessary, an optical guide layer may be located between the active layer 3 and a clad layer located above or below it.

It is to be noted that the aforementioned n-type clad layer 2, the active layer 3, and the p-type clad layer 4 are referred to as a “semiconductor laser layer”. Alternatively, the n-type clad layer 2, the active layer 3, the p-type clad layer 4, and the p-type contact layer 5 may be referred to as a “semiconductor laser layer”.

Moreover, a process for forming the semiconductor laser layer (what is referred to here is the aforementioned semiconductor crystal growth process) may be referred to as a “semiconductor laser layer forming process”.

<Formation of the Ridge>

After the aforementioned first crystal growth, the p-type clad layer 4 and the p-type contact layer 5 are subjected to etching, whereby a ridge 6 having a trapezoidal cross section is formed (a ridge forming step is performed). This ridge 6 is a striped-shaped ridge that extends in the same direction as the direction in which light is emitted (optical axis).

In the following description, the stripe direction of the ridge 6 is referred to as the “length direction (X direction)” of the semiconductor laser device (for example, the LD1), and the direction perpendicular to the stripe direction of the ridge 6 is referred to as the “width direction (Y direction)” of the semiconductor laser device LD1.

Furthermore, of the four side faces of the semiconductor laser device LD1, two are facets A1 and A2 that intersect the ridge 6 and serve as resonator facets, and the other two are facets B1 an B2 that run parallel to the stripe direction of the ridge 6.

<Second Crystal Growth>

After the formation of the ridge 6, second crystal growth is performed (an n-type semiconductor is grown), whereby a current block layer 7 is formed other than the top face of the ridge 6 (a current block forming step is performed).

The current block layer 7 makes current flow into the active layer 3 only through the top face of the ridge 6. Incidentally, the first and second crystal growth are performed by vapor deposition by using an MOCVD (metal organic chemical vapor deposition) machine.

<Formation of the P-type Electrode>

Then, on the top face of the current block layer 7, a p-type electrode (p-electrode) 8 is formed (a first type electrode forming step is performed). The p-type electrode (first type electrode) 8 includes a first electrode 9 and a second electrode 10.

Specifically, after the first electrode 9 is formed on the top face of the semiconductor laser device LD1 (after the first electrode forming step is performed), the second electrode 10 is formed on the first electrode 9 (the second electrode forming step is performed).

<<First Electrode>>

The film thickness of the first electrode 9 is so set as to be sufficiently thinner than that of the second electrode 10 in order to prevent the first electrode 9 from coming off the current block layer 7 when devices are separated from each other by cleavage. For example, the film thickness thereof is so set as to be equal to or smaller than 1 μm, preferably to be equal to or smaller than 100 nm, and more preferably to 10 to 30 nm.

Preferably, the first electrode 9 is formed of an electrode material that can provide good ohmic contact with the semiconductor layer exposed at the top face of the ridge 6, that is, the p-type contact layer 5 shown in FIG. 1.

Although the first electrode 9 covers the entire area of the top face of the semiconductor laser device LD1, it may be formed otherwise as long as it covers at least the top face of the ridge 6 that serves as a current flowing path (a detailed description will be given later).

<<Second Electrode>>

On the other hand, the second electrode 10 is formed of an electrode material consisting principally of gold (the second electrode forming step is performed).

The second electrode 10 is formed at a given distance, for example, 10 to 30 μm away from both ends (that is, the facets A1 and A2) of the ridge 6 in the X direction. Likewise, the second electrode 10 is formed at a given distance, for example, 10-30 μm away from the facets B1 and B2.

As described above, the second electrode 10 is so formed as to be away from the facets (A1, A2, B1, B2). The reason is as follows.

The film thickness of the second electrode 10 is so formed as to be thicker than that of the first electrode 9. For example, the second electrode 10 may have a film thickness of greater than 2 μm. If such a second electrode 1 is located where the device is to be cleaved, it may become impossible to cleave the electrode at the time of cleavage (at the time of a cleaving process). This may undesirably cause the second electrode 10 to come off the first electrode 9 at the time of device separation.

However, as described above, if the second electrode 10 formed of a thick film electrode material is located so as to be away from where the device is to be cleaved, it is possible to avoid the possibility of a thick film electrode (second electrode 10) coming off at the time of device separation.

<Formation of the N-type Electrode>

An n-type electrode (n-electrode) 11 is formed on the back side of the semiconductor substrate 1 (a side thereof facing away from the n-type clad layer 2 side). Preferably, the n-type electrode (second type electrode) 11 is an electrode material that can provide good ohmic contact with the semiconductor substrate 1.

Preferably, the n-type electrode 11 has a film thickness range that prevents the n-type electrode 11 from coming off the semiconductor substrate 1 at the time of device separation by cleavage. More preferably, the n-type electrode 11 has a film thickness range that offers absorption of shock caused by wire bonding. For example, the film thickness may be in the range from 0.5 μm to 2.0 μm.

The n-type electrode 11 may be formed after or prior to the formation of the p-type electrode 8.

<Device Separation>

As described above, after the electrodes (the p-type electrode 8 and the n-type electrode 11) are formed, a scribe line is formed on a wafer in the Y direction and then pressures is applied thereto, whereby the wafer is separated (cleaved) into bars.

Then, a reflective film is formed on the exposed facets A1 and A2, and then bar-shaped wafers are each separated (cleaved) in the X direction by using a scribing method or a dicing method. As a result of device separation described above, a semiconductor laser device LD1 shown in FIG. 1 is obtained.

It is to be noted that the semiconductor laser device LD1 is mounted junction down on a lead electrode portion (not shown). Specifically, the p-type electrode 8 is secured on the lead electrode by using an electrical conducting material.

On the other hand, a conductor (not shown) such as a bonding wire is connected to the n-type electrode 11. When a predetermined voltage is applied to between the p-type electrode 8 and the n-type electrode 11, the semiconductor laser device LD1 is made to operate, whereby laser light having a predetermined wavelength is emitted in the X direction from part of the active layer 3 located immediately below the ridge 6.

[Various Features of the Semiconductor Laser Device LD1]

As described above, the semiconductor laser device LD1 of the present invention is structured as follows. A semiconductor laser layer is formed on one face of the semiconductor substrate 1, and a p-type electrode 8 and an n-type electrode 11 are provided on the semiconductor laser layer side and the semiconductor substrate I side, respectively, so as to sandwich the semiconductor laser layer and the semiconductor substrate 1 between them.

The p-type electrode 8 includes a first electrode 9 and a second electrode 10 that covers the first electrode 9.

That is, in the method for fabricating the semiconductor laser device LD1 described above, a step of forming the p-electrode 8 includes a first electrode forming step of forming the first electrode 9 and a second electrode forming step of forming the second electrode 10.

In particular, when a stripe-shaped and raised ridge 6 is formed in the semiconductor laser layer, the first electrode 9 is so formed as to cover at least the top face of the ridge 6 (specifically, the p-type contact layer 5), and the second electrode 10 is so formed as to have an area smaller than the area occupied by the semiconductor laser layer.

That is, the method for fabricating the semiconductor laser device of the present invention includes a ridge forming step of forming a stripe-shaped and raised ridge 6 in the semiconductor laser layer. After the ridge forming step, the first electrode forming step is performed in such a way that the first electrode 9 is so formed as to cover at least the top face of the ridge 6.

Then, the second electrode forming step is performed in such a way that the second electrode 10 is so formed, on the first electrode 9, as to have an area smaller than the area occupied by the semiconductor laser layer.

In this way, in the semiconductor laser device LD1 of the present invention, the first electrode 9 covers the entire area of the top face of the ridge 6. This makes it possible to feed sufficient current to both stripe-direction ends of the ridge 6.

Furthermore, the second electrode 10 is made to have an area smaller than the area occupied by the semiconductor laser layer. For example, the second electrode 10 is so formed as to be away from the edges (the facets A1, A2, B1, B2) of the semiconductor laser layer.

As a result, cleaved facets (cleaved lines (facets A1, A2, B1, B2)) formed at the time of device separation do not overlap the second electrode 10. This makes it possible to reduce the possibility of the second electrode 10 coming off the first electrode 9 at the time of cleavage.

In the semiconductor laser device LD1 of the present invention, the film thickness of the first electrode 9 is made thinner than that of the second electrode 10. This makes it possible to prevent the possibility that the first electrode 9 becomes so thick that it comes off at the time of cleavage.

### Second Embodiment

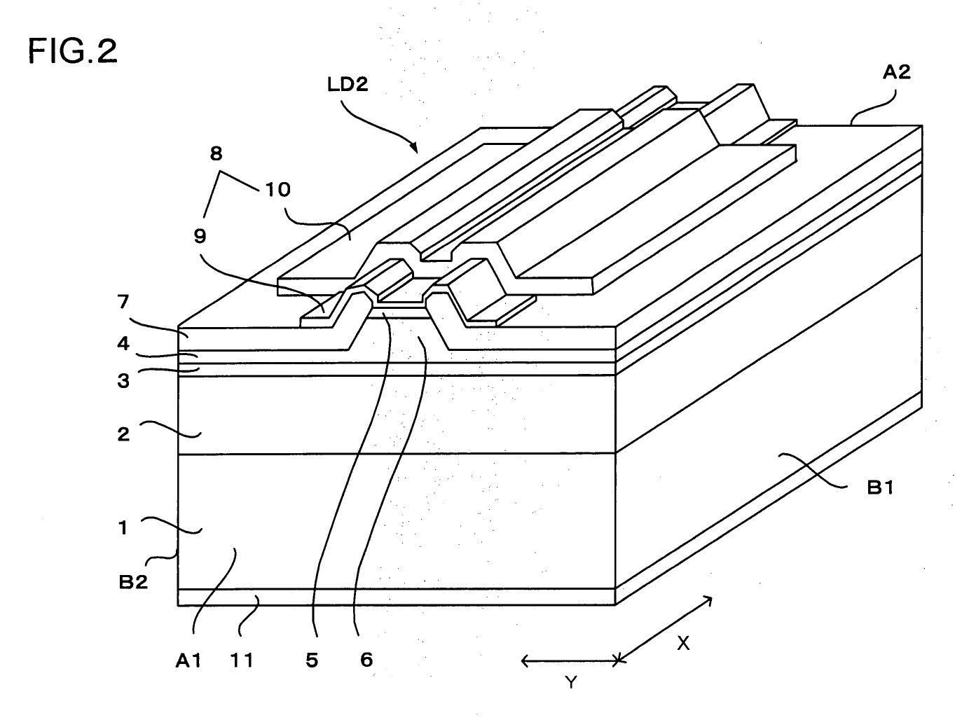

A second embodiment of the present invention will be described with reference to FIG. 2. It is to be noted that such members as find their functionally equivalent counterparts in the first embodiment are identified with the same reference numerals, and description thereof will be omitted. In the following description, only differences from the first embodiment are explained.

The second embodiment of the present invention differs from the first embodiment in the shape of a first electrode (first electrode) 9. In the first embodiment, the first electrode 9 is formed on the entire surface of the semiconductor laser device LD1, including the top face of the ridge 6. However, the present invention is not limited to this specific shape.

For example, as shown in FIG. 2, the first electrode 9 may be so formed as to cover only above the ridge 6 including at least the top face thereof. More specifically, the first electrode 9 may be formed in the shape of a stripe running in the same direction as the ridge 6 in such a way that the first electrode 9 is located at a given distance away from the facets B1 and B2 of a semiconductor laser device LD2.

In this stripe-shaped first electrode 9, the Y-direction length thereof is made shorter than the Y-direction length of the second electrode 10. This makes the second electrode 10 cover both the first electrode 9 and the current block layer 7 (make contact therewith).

With this semiconductor laser device LD2, as is the case with the semiconductor laser device LD1 described above, the first electrode 9 covers the entire area of the top face of the ridge 6. This makes it possible to feed sufficient current to both stripe-direction ends of the ridge 6.

Moreover, since the first electrode 9 is made sufficiently thinner than the second electrode 10, it is possible to eliminate the possibility of the first electrode 9 coming off at the time of device separation by cleavage.

On the other hand, the second electrode 10 that is thicker than the first electrode 9 is so formed as to be located at a given distance away from the both stripe-direction ends of the ridge 6. This makes it possible to eliminate the possibility of the second electrode 10 coming off at the time of device separation.

Furthermore, by forming the first electrode 9 in the shape of a stripe, it is possible to reduce the possibility of the first electrode 9 coming off when devices are separated from each other or the second electrode 10 is lifted off.

### Third Embodiment

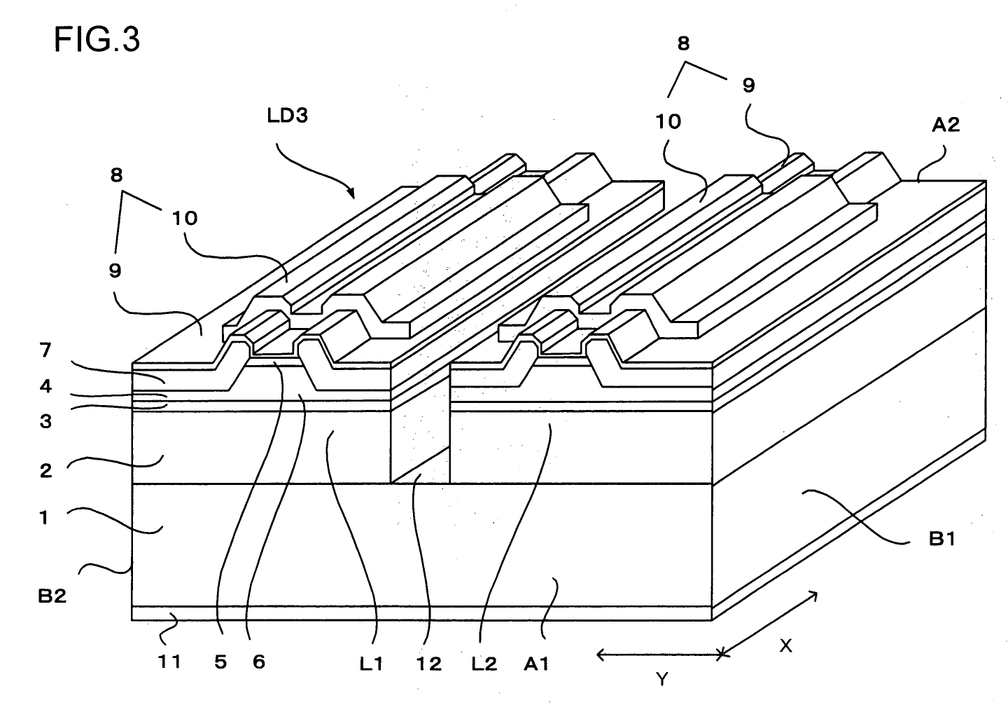

A third embodiment of the present invention will be described with reference to FIG. 3. It is to be noted that such members as find their functionally equivalent counterparts in the first and second embodiments are identified with the same reference numerals, and description thereof will be omitted. In the following description, only differences from the first and second embodiments are explained.

This embodiment differs from the first embodiment in that, instead of a single beam semiconductor laser device (LD1), a multibeam semiconductor laser device LD3 is adopted. That is, this embodiment is characterized by adopting a multibeam (monolithic) semiconductor laser device LD3 in which a plurality of semiconductor laser portions (in this example, two semiconductor laser portions (L1, L2)) are formed on a common (monolithic) semiconductor substrate 1.

The semiconductor laser portions L1 and L2 each have the same structure as described in the first embodiment. That is, in the semiconductor laser device LD3, the semiconductor laser portions L1 and L2 having the structure (p-type electrode 8) as described in the first embodiment are formed on the monolithic semiconductor substrate 1.

This embodiment deals with an example in which two semiconductor laser portions L1 and L2 are formed; however, it is also possible to form three or more semiconductor laser portions.

In the semiconductor laser device LD3, a separation groove (groove) 12 is formed between the semiconductor laser portion L1 and the semiconductor laser L2 (a groove forming step is performed). The separation groove 12 located between the semiconductor laser portion L1 and the semiconductor laser L2 electrically separates them from each other.

For example, this separation groove 12 is formed at the time of etching of the crystal grown semiconductor laser layer before a p-type electrode 8 and an n-type electrode 11 are formed in the semiconductor laser portions L1 and L2. However, the formation timing and method of the separation groove 12 are not limited to these specific timing and method (such as etching).

For example, the separation groove 12 may be formed by, for example, dicing or laser processing other than etching before or after the p-type electrode 8 and the n-type electrode 11 are formed.

Incidentally, in the semiconductor laser device LD3 provided with the separation groove 12, it is necessary to prevent the first electrode 9 and the second electrode 10 from being formed inside the separation groove 12. That is, the first electrodes 9 each have to be formed within the area occupied by a corresponding one of the semiconductor laser layers separated by the separation groove 12 (in order to prevent a short circuit).

It is for this reason that, in the process of forming the first electrode 9 and the second electrode 10 in the semiconductor laser device LD3, the p-electrode 8 (the first electrode 9 and the second electrode 10) is formed in a selective manner (that is, only on the upper faces of the semiconductor laser portions L1 and L2) by lift-off, for example.

As described above, in the semiconductor laser device LD3 of the present invention, even when a plurality of ridges 6 are formed, that is, a plurality of semiconductor laser portions (L1 and L2), each emitting laser light, are formed on the monolithic semiconductor substrate 1, the second electrode 10 is so formed as to have an area smaller than the area occupied by the semiconductor laser layer corresponding to each ridge 6.

That is, when a plurality of ridges 6 are formed in the ridge forming step, the second electrode 10 is so formed, in the second electrode forming step, as to have an area smaller than the area occupied by the semiconductor laser layer corresponding to each ridge 6.

By doing this, it is possible to obtain the aforementioned benefits (the benefits obtained by the semiconductor laser devices LD1 and LD2). Needless to say, also in the semiconductor laser device LD3, as is the case with the aforementioned semiconductor laser devices LD1 and LD2, since the first electrode 9 covers the entire area of the top face of the ridge 6, it is possible to feed sufficient current to both stripe-direction ends of the ridge 6.

As is the case with the semiconductor laser devices LD1 and LD2, also in the semiconductor laser device LD3, the first electrode 9 is made sufficiently thinner than the second electrode 10, and the second electrode 10 that is thicker than the first electrode 9 is so formed as to be located at a given distance away from both stripe-direction ends of the ridge 6.

This makes it possible to eliminate the possibility of the second electrode 10 coming off at the time of device separation by cleavage.

Furthermore, the present invention includes a groove forming step in which a separation groove 12 is formed in the semiconductor laser layer for separating a plurality of ridges 6 from each other, the plurality of ridges formed in the ridge forming step. In addition to this, in the first electrode forming step, the first electrodes 9 are each formed within the area occupied by a corresponding one of the semiconductor laser layers separated by the separation groove 12 formed in the groove forming step.

As a result, the first electrode 9 is prevented from being formed inside the separation groove 12 thus formed. This makes the semiconductor laser portions (L1, L2) electrically disconnected from each other. This eliminates the possibility of deterioration of the device characteristics of the semiconductor laser device due to, for example, a short circuit resulting from the formation of the first electrode 9 inside the separation groove 12.

### Fourth Embodiment

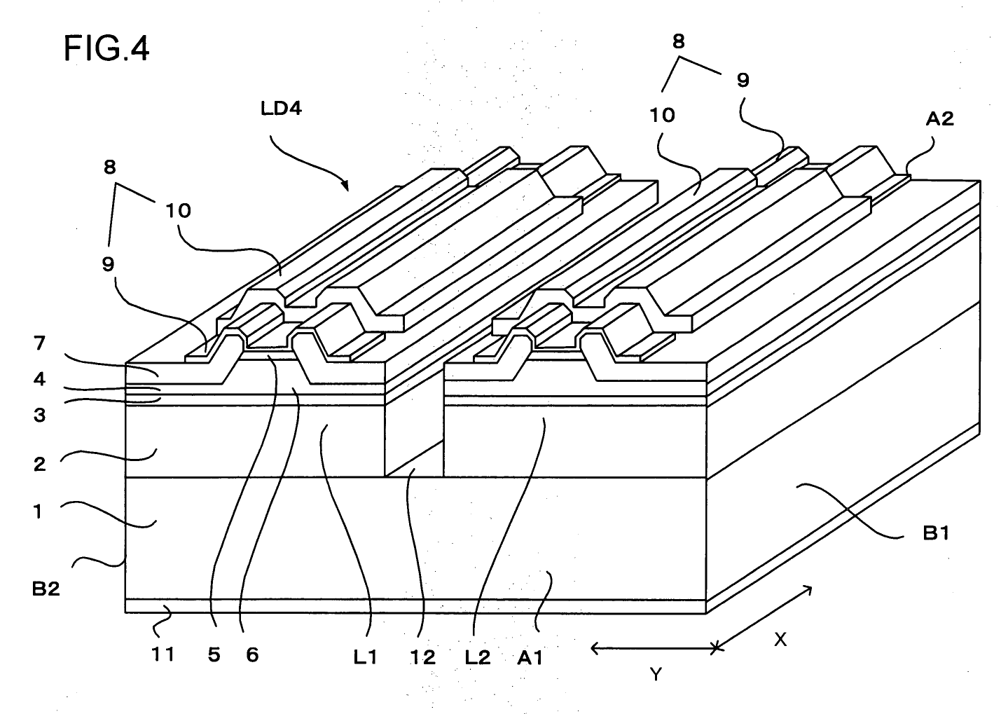

A fourth embodiment of the present invention will be described with reference to FIG. 4. It is to be noted that such members as find their functionally equivalent counterparts in the first to third embodiments are identified with the same reference numerals, and description thereof will be omitted. In the following description, only differences from the first to third embodiments are explained.

This embodiment differs from the second embodiment in that, instead of a single beam semiconductor laser device (LD2), a multibeam semiconductor laser device LD4 is adopted. That is, this embodiment is characterized by adopting a multibeam (monolithic) semiconductor laser device in which a plurality of semiconductor laser portions (in this example, two semiconductor laser portions (L1, L2)) are formed on a common (monolithic) semiconductor substrate 1.

The semiconductor laser portions L1 and L2 each have the same structure as described in the second embodiment. That is, in the semiconductor laser device LD4, the semiconductor laser portions L1 and L2 having the structure (p-type electrode 8) as described in the second embodiment are formed on the monolithic semiconductor substrate 1.

This embodiment deals with an example in which two semiconductor laser portions L1 and L2 are formed; however, it is also possible to form three or more semiconductor laser portions.

In the semiconductor laser device LD4, a separation groove 12 is formed between the semiconductor laser portions L1 and L2. The separation groove 12 located between the semiconductor laser portion L1 and the semiconductor laser L2 electrically separates them from each other.

As mentioned earlier, this separation groove 12 is formed, for example, at the time of etching of the crystal grown semiconductor laser layer before a p-type electrode 8 and an n-type electrode 11 are formed in the semiconductor laser portions L1 and L2. However, the formation timing and method of the separation groove 12 are not limited to these specific timing and method (such as etching).

For example, the separation groove 12 may be formed by, for example, dicing or laser processing other than etching before or after the p-type electrode 8 and the n-type electrode 11 are formed.

Incidentally, in the semiconductor laser device LD4 provided with the separation groove 12, it is necessary to prevent the first electrode 9 and the second. electrode 10 from being formed inside the separation groove 12. It is for this reason that, in the process of forming the first electrode 9 and the second electrode 10 in the semiconductor laser device LD4, the electrodes (the first electrode 9 and the second electrode 10) are formed in a selective manner (that is, only on the upper faces of the semiconductor laser portions L1 and L2) by lift-off, for example.

According to the semiconductor laser device LD4 described above, it is possible to obtain the same benefits as those obtained by the semiconductor laser devices LD1 to LD3 described above.

### Modified Examples of the Third and Fourth Embodiments

It is to be understood that the present invention may be practiced in any other manner than specifically described above as embodiments, and various modifications are possible within the scope of the invention.

For example, in the third and fourth embodiments described above, in each of the forming steps of the semiconductor laser portions L1 and L2, the first electrode 9 and/or the second electrode 10 (that is, at least one of the first electrode 9 and the second electrode 10) is formed simultaneously by using the same electrode material. Thus, these forming steps can be made common.

The third or fourth embodiment may be so modified that a plurality of semiconductor laser portions L1 and L2 have different light-emitting wavelengths. That is, a multiwavelength multibeam semiconductor laser device having different light-emitting wavelengths may be adopted (for example, a semiconductor laser device that can output two wavelengths may be adopted).

It is to be noted that, even when the plurality of semiconductor laser portions L1 and L2 have different light-emitting wavelengths, in each of the forming steps of the semiconductor laser portions L1 and L2, the first electrode 9 and/or the second electrode 10 may be formed simultaneously as described above by using the same electrode material.

As described above, by forming the first electrode 9 and second electrode 10 simultaneously by using the same electrode material, the forming steps can be made common. On the other hand, it is also possible to form the first electrode 9 and the second electrode 10 by using different electrode materials commensurate with the semiconductor laser portions L1 and L2.

In either case, it is needless to say that the same benefits as those obtained in the third and fourth embodiments can be obtained.

Incidentally, in the semiconductor laser devices LD1 to LD4 described above, it is not necessary to form a buried layer on the ridge 6. This helps reduce the number of parts and fabrication processes. Furthermore, this helps achieve a semiconductor laser device having satisfactory heat dissipation.

### Fifth Embodiment

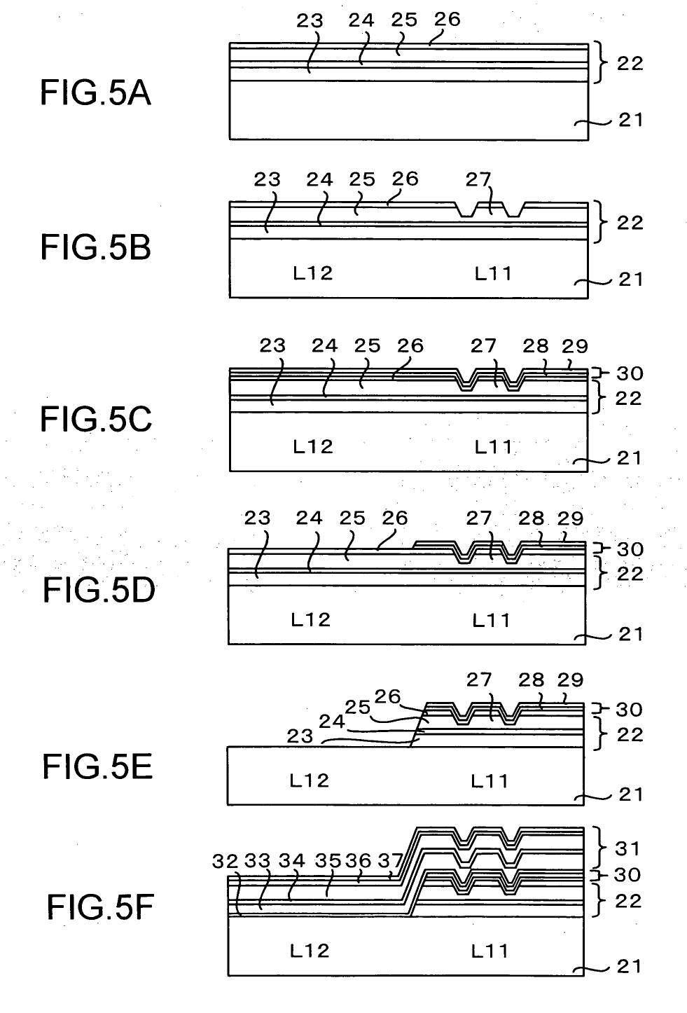

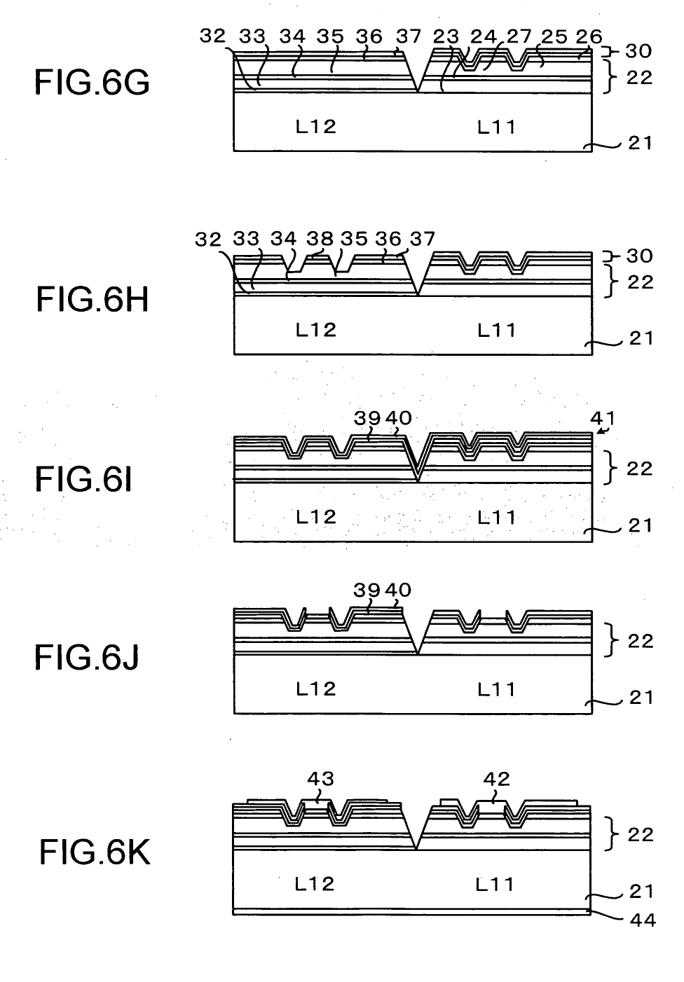

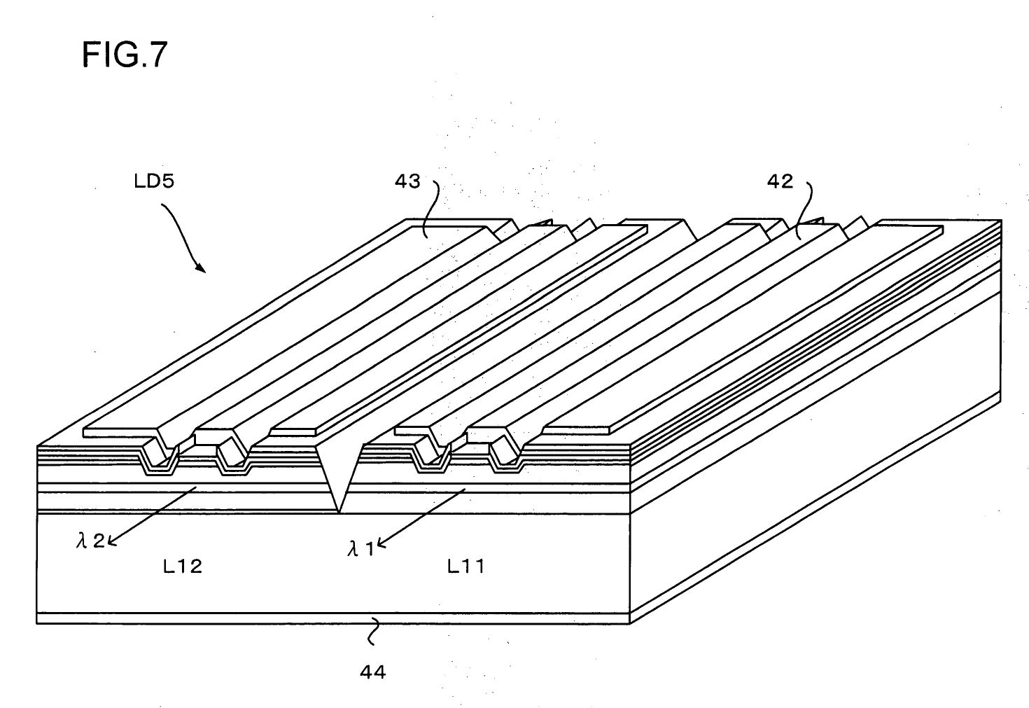

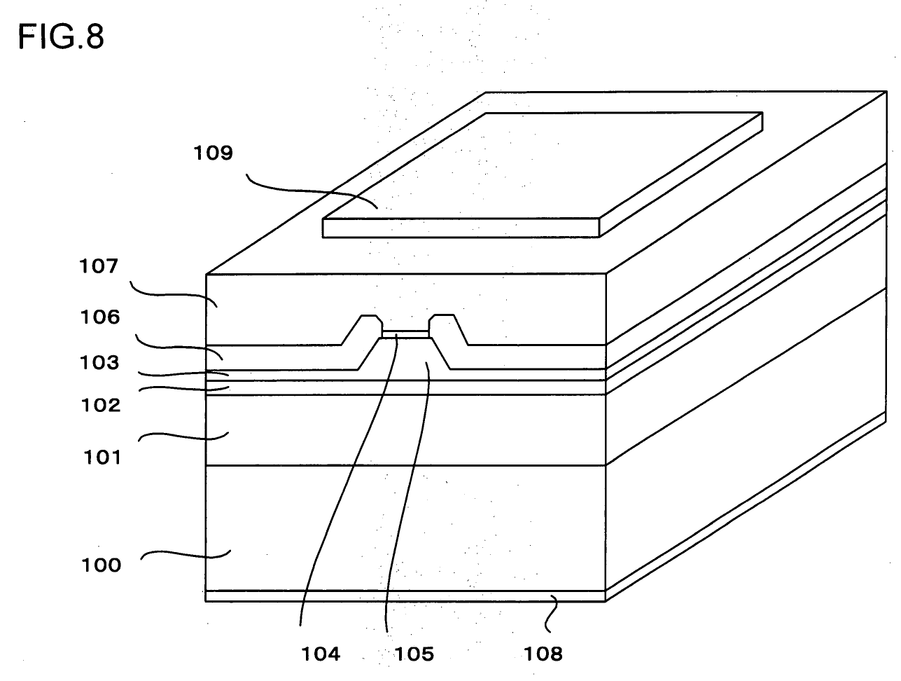

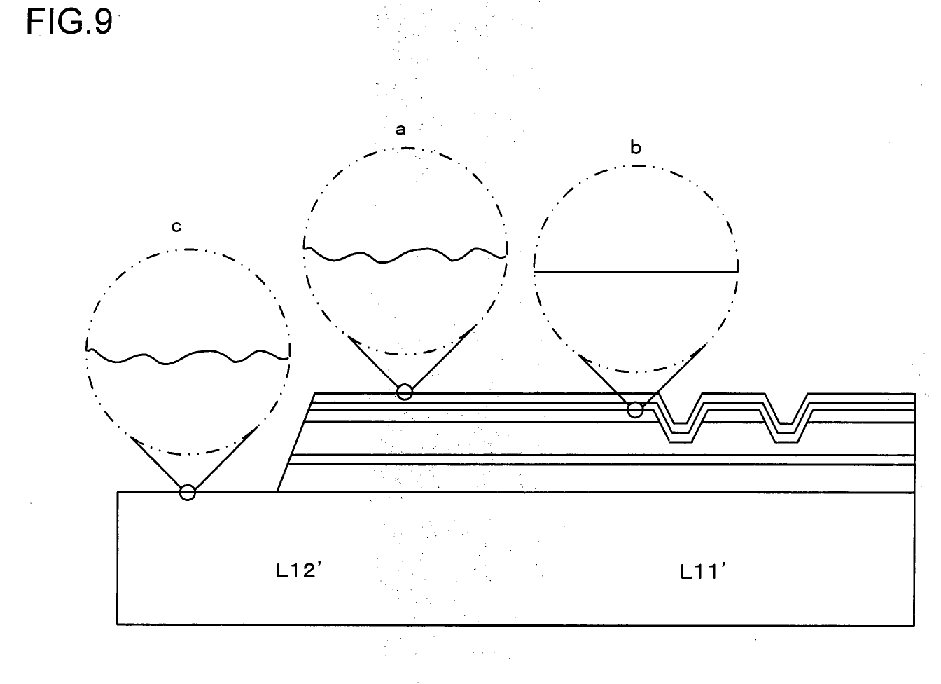

Here, referring to FIGS. 5A to 5F and FIGS. 6G to 6K, a semiconductor laser device LD5 (see FIG. 7, which will be described later) will be described as an example of the aforementioned semiconductor laser device provided with a plurality of semiconductor laser portions L11 and L12 having different light-emitting wavelengths. For reference numerals that cannot be shown in these drawings, reference should be made to other drawings for convenience sake.

Specifically, a description will be given of a fabrication procedure of the dual-wavelength semiconductor laser device LD5 provided with a first semiconductor laser portion L11 having a central wavelength in the infrared region and a second semiconductor laser portion L12 having a central wavelength in the red region.

[Method for Fabricating the Semiconductor Laser Device]

<First Crystal Growth>

As shown in FIG. 5A, first crystal growth is performed on a semiconductor substrate 21 by MOCVD (a first semiconductor crystal growth step is performed), whereby a multiple-layer structure 22 is so formed as to have a double-hetero structure.

This multiple-layer structure 22 (first crystal growth layer 22; semiconductor laser layer) has the following layers laid on top of another in the order mentioned on the semiconductor substrate 21 formed of n-type GaAs, for example (that is, from the semiconductor substrate 21 side): an n-type clad layer 23 formed of AlGaAs, for example, a multiquantum well (MQW) active layer 24 formed of AlGaAs, for example, and a p-type clad layer 25 formed of AlGaAs, for example, and a p-type GaAs layer 26.

This multiple-layer structure 22 (first crystal growth layer 22) formed so as to have a double-hetero structure is formed in the MOCVD machine by a sequential film formation process. The aforementioned semiconductor substrate 1 formed of n-type GaAs is so set as to have a film thickness of around 100 μm.

In this double-hetero structure, the bandgap energy of the n-type clad layer 23 and the p-type clad layer 25 is made greater than that of the active layer 4.

Specifically, the A1 composition (ratio) of the n-type clad layer 23 and the p-type clad layer 25 is made greater than that of the active layer 24, whereby the bandgap energy of the former is made greater than that of the latter.

The A1 composition of the active layer 24 is so selected (set) that the light-emitting peak wavelength (λ1) is located around 790 nm in the infrared region.

Preferably, a thin etching stopper layer is inserted somewhere in the middle of the p-type clad layer 25 so that a ridge 27 has a fixed height.

Used as the etching stopper layer is a material such as an AlGaAs material whose A1 composition is so set as to be sufficiently lower than that of the p-type clad layer 25, or a GaAs material.

<Formation of the Ridge (Ridge for L11)>

After the first crystal growth, as shown in FIG. 5B, the ridge 27 for the first semiconductor laser portion L11 is formed (a first ridge forming step is performed).

The ridge 27 is formed as follows. A region other than a region to be removed by etching is coated with a resist, and then the product thus obtained is soaked in an etchant (etching solution). By performing etching as described above, part of the crystal grown by the first crystal growth is removed, whereby the stripe-shaped ridge 27 is formed.

Incidentally, by inserting a thin etching stopper layer somewhere in the middle of the p-type clad layer 25, it is possible to make the ridge 27 have a fixed height.

<Second Crystal Growth>

After the formation of the ridge 27, as shown in FIG. 5C, second crystal growth is performed (a second semiconductor crystal growth step is performed) on the semiconductor substrate 21 (specifically, on the p-type GaAs layer 26 in the double-hetero structure 22).

As is the case with the first crystal growth, the second crystal growth is also performed by MOCVD.

Specifically, the second crystal growth results in the formation of a multiple-layer structure 30 (second crystal growth layer 30; semiconductor laser layer) having the following layers laid on top of another in the order mentioned on the p-type GaAs layer 26: an n-type layer 28 formed of AlGaAs and an n-type layer 29 formed of GaAs.

The A1 composition of the n-type layer 28 formed of AlGaAs is set to a value greater than 0.51. In this example, it is set to 0.65. The above-described n-type layer 8 and the n-type layer 29 are located on both sides of the ridge 27 and serve as a current block layer.

In the second crystal growth, to suppress crystal deterioration of the multiple-layer structure (double-hetero structure) 22 formed by the first crystal growth, the crystal growth temperature is so set as to be lower than an average crystal growth temperature of the first crystal growth (for example, the crystal growth temperature is so set as to be about 100° C. lower than an average crystal growth temperature of the first crystal growth).

As a result, the crystallinity of the second crystal growth layer (the n-type layer 8, the n-type layer 9) is lower than that of the first crystal growth layer 22 (the n-type clad layer 23, the active layer 24, the p-type clad layer 25, the p-type GaAs layer 26).

That is, projections and depressions are formed on the surface of the second crystal growth layer (second crystal growth layer 30).

<Partial Removal of the Second Crystal Growth Layer>

After the second crystal growth, as shown in FIG. 5D, the multiple-layer structure 30 located where the second semiconductor laser portion L12 is to be formed is removed (the second crystal growth layer 30 is partially removed) (a first removing step is performed).

Specifically, removal (partial removal) of the multiple-layer structure 30 is performed as follows. A region other than a region to be removed is coated with a resist, and then the product thus obtained is soaked in an etchant. More specifically, the n-type layer 29 of GaAs is first etched, and then the n-type layer 28 of AlGaAs is etched.

In etching of the n-type layer 29 of GaAs, a phosphoric acid etchant is used.

On the other hand, in etching of the n-type layer 28 of AlGaAs, an acid etchant that has selectivity to GaAs (that is capable of selective etching of GaAs), such as a hydrochloric acid etchant, a hydrofluoric acid etchant, or a buffered hydrofluoric acid etchant, is used.

That is, different etchants are used for etching of different n-type layers: the n-type layer 29 of GaAs and the n-type layer 28 of AlGaAs.

Preferably, the n-type layer 28 of AlGaAs has a high etching selectivity to the underlying p-type GaAs layer 26 (contact layer 26 formed of GaAs) and has improved optical characteristics. It is for this reason that the A1 composition of the n-type layer 28 of AlGaAs is set to a value greater than 0.51.

In this way, the n-type layer 28 of AlGaAs is selectively removed by using an acid etchant such as a hydrochloric acid etchant, a hydrofluoric acid etchant, or a buffered hydrofluoric acid etchant. By doing this, the p-type GaAs layer 26 (contact layer 26) that is the uppermost layer formed by the first crystal growth is exposed.

The exposed surface of the p-type GaAs layer 26 is formed by the first crystal growth, which is performed at a higher temperature than the second crystal growth. As a result, the crystallinity of the p-type GaAs layer 26 is high, and the exposed part of the p-type GaAs layer 26 is relatively flat and suffers less from irregularities.

<Partial Removal of the First Crystal Growth Layer>

Then, by using a common etchant (for example, a phosphoric acid etchant), the layer 22 (the layer 22 formed by the first crystal growth) including the p-type GaAs layer 26, the p-type clad layer 25 formed of AlGaAs, the active layer 24 formed of AlGaAs, and the n-type clad layer 23 formed of AlGaAs is removed by etching (a second removing step is performed).

Specifically, as shown in FIG. 5E, the first crystal growth layer 22 is etched at a time until the substrate 21 is exposed. It is to be noted that, even if projections and depressions are formed on the surface of the second crystal growth layer 30 by the above-described etching process, the influences of these projections and depressions are cancelled out by the earlier etching (partial removal of the second crystal growth layer 30).

Thus, the surface of a region where the second semiconductor laser portion L12 is to be located (the surface of the semiconductor substrate 21) is flat.

<Third Crystal Growth>

Then, as shown in FIG. 5F, third crystal growth is performed on the semiconductor substrate 21 by MOCVD. Specifically, a multiple-layer structure 31 (third crystal growth layer 31; semiconductor laser layer) is so formed as to have a double-hetero structure (a third semiconductor crystal growth step is performed).

By this third crystal growth, on the semiconductor substrate 21, an n-type layer 32 formed of GaInP, an n-type clad layer 33 formed of AlGaInP, a multiquantum well (MQW) active layer 34 formed of AlGaInP, a p-type clad layer 35 formed of AlGaInP, a p-type GaInP layer 36, and a p-type GaAs layer 37 are laid on top of another in this order.

This multiple-layer structure 31 (third crystal growth layer 31) formed so as to have a double-hetero structure is formed in the MOCVD machine by a sequential film formation process.

In this double-hetero structure, the bandgap energy of the n-type clad layer 33 and the p-type clad layer 35 is made greater than that of the active layer 34.

Specifically, the A1 composition (ratio) of the n-type clad layer 33 and the p-type clad layer 35 is made greater than that of the active layer 34, whereby the bandgap energy of the former is made greater than that of the latter.

The A1 composition of the active layer 34 is so selected (set) that the light-emitting peak wavelength (λ2) is located around 655 nm in the red region.

Preferably, a thin etching stopper layer is inserted somewhere in the middle of the p-type clad layer 35 so that a ridge 38 (see FIG. 6H, which will be described later) has a fixed height.

Used as the etching stopper layer is a material such as an AlGaInP material whose A1 composition is so set as to be sufficiently lower than that of the p-type clad layer 35, or a GaInP material.

<Partial Removal of the Third Crystal Growth Layer>

Then, as shown in FIG. 6G, the third crystal growth layer 31 (third crystal growth layer 31) is removed except for a region to be used as the second semiconductor laser portion L12 (a third removing step is performed).

In this removing step, a phosphoric acid etchant for GaAs and AlGaAs and, as an etchant for AlGaInP or GaInP, a mixture of hydrobromic acid (HBr) and hydrochloric acid are used one by one.

By this removing step, the layer 31 formed by the third crystal growth (third crystal growth layer 31) located above the first semiconductor laser portion. L11 is removed.

<Formation of the Ridge (Ridge for L12)>

Then, as shown in FIG. 6H, the ridge 38 for the second semiconductor laser portion L12 is formed (a second ridge forming step is performed).

This ridge 38 is formed as follows. First, a region other than a region to be etched is covered with a mask of, for example, oxide silicon, and then the product thus obtained is soaked in an etchant. By performing etching as described above, part of the crystal grown by the third crystal growth is removed, whereby the stripe-shaped ridge 38 is formed.

Incidentally, by inserting a thin etching stopper layer somewhere in the middle of the p-type clad layer 35, it is possible to make the ridge 38 have a fixed height.

<Fourth Crystal Growth>

After the formation of the ridge 38, as shown in FIG. 6I, on the semiconductor substrate 21 (specifically, on the p-type GaAs layer 37 of the double-hetero structure 31), fourth crystal growth is performed (a fourth semiconductor crystal growth step is performed).

As is the case with the first to third crystal growth, the fourth crystal growth is performed by MOCVD.

Specifically, the fourth crystal growth results in the formation of a multiple-layer structure 41 (fourth crystal growth layer 41; semiconductor laser layer) having the following layers laid on top of another in the order mentioned on the p-type GaAs layer 37: an n-type layer 39 formed of AlInP and an n-type layer 40 formed of GaAs.

The above-described n-type layer 39 and the n-type layer 40 are located on both sides of the ridge 38 and serve as a current block layer.

In the fourth crystal growth, to suppress crystal deterioration of the multiple-layer structure (double-hetero structure) 31 formed by the third crystal growth, the crystal growth temperature is so set as to be lower than an average crystal growth temperature of the third crystal growth (for example, the crystal growth temperature is so set as to be about 100° C. lower than an average crystal growth temperature of the third crystal growth).

<Formation of the Opening>

Next, as shown in FIG. 6J, openings are formed in the current block layer (the n-type layer 39, the n-type layer 40) formed over the peak portions of the ridge 27 of the first semiconductor laser portion L11 and the ridge 38 of the second semiconductor laser portion L12 (an opening forming step is performed).

<Formation of the Electrode (N-type Electrode, P-type Electrode)>

After current paths to the ridges 27 and 38 are formed by the formation of the openings, as shown in FIG. 6K, a p-type electrode 42 and a p-type electrode 43 are formed in the first semiconductor laser portion L11 and the second semiconductor laser portion L12 respectively so as to cover the openings.

Additionally, a common n-type electrode 44 is formed on the semiconductor substrate 21, on which the first semiconductor laser portion L11 and the second semiconductor laser portion L12 are formed (an electrode forming step is performed).

<Device Separation (Cleaving Process)>

Through the procedure described above, the semiconductor laser devices LD5, each having a plurality of semiconductor laser portions (L11, L12), are formed on a wafer, and the wafer thus obtained is separated into bars by using a scribing method, for example.

A coating for adjusting the reflectivity is formed on a pair of facets constituting a resonator, and then the bars thus obtained are separated into individual devices. In this way, the dual-wavelength monolithic semiconductor laser device LD5 shown in the perspective view of FIG. 7 is obtained.

When a predetermined voltage is applied to the p-type electrode 42 and the n-type electrode 44, current flows through the peak portion of the ridge 27, whereby laser light having a wavelength of λ1 is emitted from the semiconductor laser portion L11 in the direction of an arrow shown in FIG. 7 (in the stripe direction).

On the other hand, when a predetermined voltage is applied to the p-type electrode 43 and the n-type electrode 44, current flows through the peak portion of the ridge 38, whereby laser light having a wavelength of λ2 is emitted from the semiconductor laser portion L12 in the direction of an arrow shown in FIG. 7 (in the stripe direction).

[Various Features of the Method for Fabricating the Semiconductor Laser Device]

As described above, in the method for fabricating the semiconductor laser device LD5 of the present invention, the semiconductor laser layer forming process for forming a semiconductor laser layer on which a plurality of ridges 27 and 38 are formed includes a plurality of semiconductor laser portion forming steps of forming semiconductor laser layers (semiconductor laser portions L11 and L12) corresponding to the ridges 27 and 38.

That is, the semiconductor laser layer forming process includes a semiconductor laser portion forming step of forming the semiconductor laser portion L11 and a semiconductor laser portion forming step of forming the semiconductor laser portion L12.

Each semiconductor laser portion forming step includes a plurality of stages of semiconductor crystal growth steps, and also includes a plurality of removing steps of removing the semiconductor laser layers (for example, the first crystal growth layer 22 and the second crystal growth layer 30) formed by the different stages of semiconductor crystal growth steps.

For example; the plurality of removing steps are performed in different stages, and each removing step removes a corresponding one of the semiconductor laser layers (for example, the first crystal growth layer 22 and the second crystal growth layer 30) formed by the different stages of semiconductor crystal growth steps.

That is, there are included different removing steps corresponding to the plurality of crystal growth layers (that is, different removing steps each removing only corresponding one of the plurality of crystal growth layers).

In the monolithic semiconductor laser device LD5 described above, a plurality of semiconductor laser portions (L11, L12) are formed on a monolithic semiconductor substrate 21. It is for this reason that the semiconductor laser portions (L11, L12) are located in different regions on the monolithic semiconductor substrate 21.

In that case, after one semiconductor laser portion L11 is formed on the semiconductor substrate 21 through one semiconductor laser portion forming step, it is necessary to remove the semiconductor laser layer corresponding to a region (remaining region) other than the semiconductor laser portion L11 thus formed, because the other semiconductor laser portion L12 is formed in this remaining region.

Here, in the method for fabricating the semiconductor laser device of the present invention, the semiconductor laser layer that has already been formed is removed in different stages. Specifically, the semiconductor laser layer including a plurality of semiconductor crystals (for example, a first crystal growth layer 22 and a second crystal growth layer 30) is removed in such a way that the different semiconductor crystals (crystal growth layers) are removed one by one.

That is, the method for fabricating the semiconductor laser device LD5 of the present invention includes a plurality of removing steps, one for each of the crystal growth layers, for removing the crystal growth layers, whereby the semiconductor laser layer is removed in different stages.

As described above, by performing the removal in different stages, the adverse influences of the poor flatness of the uppermost layer (second crystal growth layer 30) are cancelled out by an earlier removing step (first removing step) performed before a removing step by which the semiconductor substrate 21 is exposed. That is, the semiconductor substrate 21 is prevented from being directly affected by the projections and depressions, for example, formed in the uppermost layer.

Through a plurality of removing steps (that is, through a second removing step), the exposed surface of the semiconductor substrate 21 achieves a very high degree of flatness. This helps improve the crystallinity of the semiconductor laser layer of the other semiconductor laser portion L12, making it possible to form a semiconductor laser device LD5 having desired device characteristics.

### Modified Examples of the Fifth Embodiment

It is to be understood that the present invention may be practiced in any other manner than specifically described above as embodiments, and various modifications are possible within the scope of the invention.

For example, the fifth embodiment described above deals with a case in which, in the partial removal of the second crystal growth layer, the uppermost layer (p-type GaAs layer 26) formed by the first crystal growth is etched until it is exposed, and then the first crystal growth layer is partially removed. However, the present invention is not limited to this specific procedure.

For example, etching may be performed until one of the layer formed by the first crystal growth (first crystal growth layer 22) other than the uppermost layer thereof is exposed.

That is, by etching the first crystal growth layer 22 and the second crystal growth layer 30 until one of the layer formed by the first crystal growth other than the uppermost layer is exposed, the influences of the second crystal growth are prevented.

By performing etching as described above, a flat surface that suffers less from irregularities is exposed, and then the remaining crystal growth layer (the remaining portion of the first crystal growth layer 22) formed by the first crystal growth is removed by etching. By doing this, the surface of the semiconductor substrate 21 exposed by etching suffers less from irregularities and becomes flat.

### Other Embodiments

It is to be understood that the present invention may be practiced in any other manner than specifically described above as embodiments, and various modifications are possible within the scope of the invention.

For example, the p-type electrodes 42 and 43 described in the fifth embodiment may have, like the p-type electrode described in the first to fourth embodiments, a two-layer structure.

### INDUSTRIAL APPLICABILITY

The present invention finds application, for example, in semiconductor laser devices (for example, semiconductor laser devices that emit laser light having a plurality of wavelengths or examples of such devices including monolithic semiconductor laser devices) that are used as a light source of an information recording and playback apparatus that records and plays back information on and from a recording medium such as a CD-R/RW or a DVD-R/±RW, or a light source for optical communications. The present invention finds application also in the fabrication of such devices.

1-26. (canceled)

27. A ridge stripe semiconductor laser device comprising an active layer, upper and lower clad layers that sandwich the active layer therebetween, a stripe-shaped ridge formed in part of the upper clad layer, and a current block layer that covers both sides of the stripe-shaped ridge other than a top face thereof,
wherein a first electrode is formed on an upper face of the semiconductor laser device, and a second electrode is formed on the first electrode,
wherein the first electrode is made thinner than the second electrode, and is so formed as to cover at least an entire area of the top face of the ridge, and
wherein the second electrode is formed at a given distance away from both stripe-direction ends of the ridge.

28. A multibeam semiconductor laser device comprising, on a common semiconductor substrate, a plurality of ridge stripe semiconductor laser portions, each comprising an active layer, upper and lower clad layers that sandwich the active layer therebetween, a stripe-shaped ridge formed in part of the upper clad layer, and a current block layer that covers both sides of the stripe-shaped ridge other than a top face thereof,
wherein a first electrode is formed on an upper face of each of the semiconductor laser portions, and a second electrode is formed on the first electrode,
wherein the first electrode is made thinner than the second electrode, and is so formed as to cover at least an entire area of the top face of the ridge, and
wherein the second electrode is formed at a given distance away from both stripe-direction ends of the ridge.

29. The semiconductor laser device according to claim 27,
wherein a width direction length of the second electrode is longer than a width direction length of the first electrode.

30. The semiconductor laser device according to claim 28,
wherein a width direction length of the second electrode is longer than a width direction length of the first electrode.

31. The semiconductor laser device according to claim 28,
wherein, between the plurality of semiconductor laser portions, a groove for electrically separating the semiconductor laser portions from each other is formed, and
wherein the first electrode is formed away from the groove.

32. A method for fabricating a ridge stripe semiconductor laser device comprising an active layer, upper and lower clad layers that sandwich the active layer therebetween, a stripe-shaped ridge formed in part of the upper clad layer, and a current block layer that covers both sides of the stripe-shaped ridge other than a top face thereof, the method for fabricating a ridge stripe semiconductor laser device comprising:
a first electrode forming step of forming a first electrode in such a way that at least an entire area of the top face of the ridge is covered therewith;
a second electrode forming step of forming a second electrode on the first electrode; and
a cleaving step of cleaving a facet of the semiconductor laser device that intersects the stripe-shaped ridge at right angles,
wherein, in the first electrode forming step, the first electrode is made thinner than the second electrode, and
wherein, in the second electrode forming step, the second electrode is formed at a given distance away from both stripe-direction ends of the ridge.

33. A method for fabricating a multibeam semiconductor laser device, the multibeam semiconductor laser device comprising, on a common semiconductor substrate, a plurality of ridge stripe semiconductor laser portions, each comprising an active layer, upper and lower clad layers that sandwich the active layer therebetween, a stripe-shaped ridge formed in part of the upper clad layer, and a current block layer that covers both sides of the stripe-shaped ridge other than a top face thereof, the method for fabricating a multibeam semiconductor laser device comprising:
a first electrode forming step of forming a first electrode in such a way that at least an entire area of the top face of each ridge is covered therewith;
a second electrode forming step of forming a second electrode on the first electrode; and
a cleaving step of cleaving a facet of the semiconductor laser device that intersects the stripe-shaped ridge at right angles,
wherein, in the first electrode forming step, the first electrode is made thinner than the second electrode, and
wherein, in the second electrode forming step, the second electrode is formed at a given distance away from both stripe-direction ends of the ridge.

34. The method for fabricating a semiconductor laser device according to claim 32,
wherein, by the second electrode forming step, a width direction length of the second electrode is made longer than a width direction length of the first electrode.

35. The method for fabricating a semiconductor laser device according to claim 33,
wherein, by the second electrode forming step, a width direction length of the second electrode is made longer than a width direction length of the first electrode.

36. The method for fabricating a semiconductor laser device according to claim 33, further comprising:
a groove forming step of forming a groove between the plurality of semiconductor laser portions for electrically separating the semiconductor laser portions from each other,
wherein, in the first electrode forming step, the first electrode is formed away from the groove.

37. The method for fabricating a semiconductor laser device according to claim 32,
wherein at least one of the first electrode forming step and the second electrode forming step uses lift-off for electrode formation.

38. The method for fabricating a semiconductor laser device according to claim 33,
wherein crystal growth including first crystal growth and second crystal growth is performed on the semiconductor substrate for forming a first semiconductor laser portion,
wherein, after a crystal grown by the first and second crystal growth in another region other than where the first semiconductor laser portion is left is removed, crystal growth is performed on the semiconductor substrate for forming a second semiconductor laser in the another region on the semiconductor substrate,
when the crystal grown by the first and second crystal growth in the another region is removed, the method for fabricating a semiconductor laser device further comprising:
a second crystal growth layer removing step of removing the crystal grown by the second crystal growth in such a way that a layer of the crystal grown by the first crystal growth is exposed; and
a first crystal growth layer removing step of removing the crystal grown by the first crystal growth.

39. The method for fabricating a semiconductor laser device according to claim 33,
wherein a growth temperature at a time of the second crystal growth is so set as to be lower than a growth temperature at a time of the first crystal growth.
